(19) United States
(12) Patent Application Publication
(10) Pub. No.: US 2023/0137818 A1
(43) Pub. Date: May 4, 2023

(54) HIGH-FREQUENCY WAVE APPLICATOR, ASSOCIATED COUPLER AND DEVICE FOR PRODUCING A PLASMA

(71) Applicants: UNIVERSITE GRENOBLE ALPES, Saint Martin D'Heres (FR); INSTITUT POLYTECHNIQUE DE GRENOBLE, Grenoble (FR); CENTRE NATIONAL DE LA RECHERCHE SCIENTIFIQUE, Paris (FR)

(72) Inventors: Ana LACOSTE, Saint Egreve (FR); Alexandre BES, Vourey (FR)

(21) Appl. No.: 17/802,595

(22) PCT Filed: Feb. 25, 2021
(86) PCT No.: PCT/EP2021/054715

§ 371 Date: Aug. 26, 2022

(30) Foreign Application Priority Data
Feb. 27, 2020 (FR) FR2001952

(51) Int. Cl. H05H 1/46; C23C 16/511

(52) U.S. Cl. CPC H05H 1/463; C23C 16/511; H05H 2242/10; H05H 2245/40

(57) ABSTRACT

A high-frequency wave applicator for producing a plasma, including an inner conductor, and an outer conductor forming a coaxial structure, and a propagation medium of a high-frequency wave in a main propagation direction (x), including a passage dielectric of the wave having a sealing solid body disposed between the inner conductor and the outer conductor. Advantageously, the inner conductor has a first outer dimension d₁ in a transverse direction (y), perpendicular to the main propagation direction (x), and the outer conductor has an inner dimension d₂ in the transverse direction (y), such that 0.2<(d₂−d₁)/d₂<0.55 allows improvement of the dissipation of the energy flows on the surface of the applicator.

### TECHNICAL FIELD

The present invention relates to the field of producing plasma excited by a high-frequency wave. It has a particularly advantageous application in producing high-power plasma (power leading to power densities greater than 10 W/cm²) and in the range of high pressures (pressure greater than 1 Torr, corresponding to around 133 Pa in the international unit system).

### STATE OF THE ART

Numerous deposition techniques are plasma-assisted. For example, the deposition of a polycrystalline silicon or diamond film on a substrate can advantageously be performed by such techniques. It is reminded that a plasma is a conductive gas medium constituted of electrons, ions and neutral particles, and electrically macroscopically neutral. A plasma is in particular obtained by ionisation of a gas by electrons. In this case, plasmas excited by high-frequency electromagnetic waves are interesting, and more specifically, the range of microwaves. Certain applications require a deposition on wide surfaces, and therefore the generation of a uniform plasma in an extended production zone. For this, several technological solutions exist.

One of these solutions consists of spatially distributing high-frequency waves, and in particular microwaves, by using a waveguide wherein the waves are propagated and injected, via injection slots, in a chamber where the deposition is performed. However, the waveguides remain bulky and undesirable couplings between the waves injected via different injection slots can limit the stability of the plasma.

Another solution consists of distributing couplers independently powered with high-frequency waves. Generally, a coupler for producing a plasma is configured to transfer an electromagnetic wave of a rear end, connected to a wave generator, at a front end, where the coupling of the wave with electrons allows to generate a plasma.

To transfer the waves and couple them with the electrons in order to generate a plasma, the coupler comprises a front terminal part, named below as applicator. The applicator comprises a coaxial structure generally open at its front end where an electromagnetic field leads and radiates in the vacuum chamber of a plasma production device.

As illustrated by FIG. 1, a coupler has a rear end connected to a wave generator 5, and comprises a wave applicator, generally constituted of two electrical conductors: an inner conductor 11 and an outer conductor 12, together forming a coaxial structure 10, the inner conductor 11 and the outer conductor 12 being separate together by a wave dielectric propagation medium 13. The applicator can be disposed at a wall 300 of the chamber 30 of the device or inserted at least partially in the chamber.

The propagation medium 13 is constituted of at least one dielectric transparent to waves. The propagation medium 13 can comprise different dielectric materials disposed by sections. The propagation medium contains at least one wave passage dielectric 130 which has a solid body configured to obtain a vacuum sealing between at least one part of the propagation medium 13, for example to the atmospheric pressure, and the vacuum chamber 30 of the plasma generation device. The passage dielectric 130 can, for example, be positioned at the front end of the applicator, or, as represented in FIG. 1, removed with respect to this end.

Moreover, a coupler is known from document WO03103003 A1, aiming to produce a plasma layer on the surface of the wall of the chamber of a plasma generation device. The coupler comprises an inner conductor substantially flush with the wall of the chamber, the inner conductor and the wall of the chamber being separated by a space coaxial to the inner conductor, forming the propagation medium. The coaxial space is filled at the end of the coupler by a wave passage dielectric having a solid body.

High-frequency wave applicators can however be subjected to significant energy flows at their front end, in contact with the plasma, and in particular when the coupler operates at high power and at high pressure. These energy flows are conveyed by significant heat quantities, inducing thermomechanical stresses. These constraints can lead to stresses and deformations of the elements constituting the applicator, even leading to their fracture. Thus, the distribution of waves by couplers remains limited to intermediate pressure ranges, not exceeding, generally, 0.5 Torr. This limits their use for deposits demanding, in addition to a high power, high pressures, like for example the deposition of diamond.

An aim of the present invention is therefore to propose a high-frequency wave applicator allowing a good power transfer, even a good coupling between an electromagnetic wave and electrons for the production of a plasma, by improving the dissipation of energy flows.

Other aims, features and advantages of the present invention will appear upon examining the following description and the accompanying drawings. It is understood that other advantages can be incorporated.

### SUMMARY

To achieve this aim, according to a first aspect, a high-frequency wave applicator for a coupler for producing a plasma is provided, comprising:
an inner conductor and an outer conductor together forming a coaxial structure extending in a main propagation direction of the wave inside the coaxial structure,
a high-frequency wave propagation medium delimited by an outer surface of the inner conductor and an inner surface of the outer conductor, and comprising a so-called high-frequency wave passage dielectric, the passage dielectric comprising a sealing solid body disposed between the inner conductor and the outer conductor,
   the inner conductor has, in a transverse direction perpendicular to the main propagation direction, a first outer dimension d₁ taken between two points of its outer surface relatively opposite an axis of the coaxial structure, and the outer conductor has, in the transverse direction, an inner dimension d₂ taken between two points of its inner surface relatively opposite the axis of the coaxial structure.

Advantageously, the first outer dimension d₁ and the inner dimension d₂ are such that:

$$0.2 < \frac{{d}_{2} - {d}_{1}}{{d}_{2}} < 0.55$$

This ratio of dimensions of the inner conductor and of the outer conductor allows a good surface distribution of power, while maintaining a good coupling with the plasma and a low level of insertion losses. Thus, the applicator allows to generate a high-power and high-pressure plasma, while improving the dissipation of the energy flows on the surface of the applicator, and in particular on the surface of a front end of the inner conductor. The reliability of the applicator is thus increased, which allows to improve the stability and the reproducibility of the methods wherein the applicator is used. The applicator can thus be used for producing high-power plasma and in the range of high pressures.

Moreover, the surface distribution of power allows to extend the power deposition zone, and therefore that of producing plasma.

The applicator is particularly adapted to plasma-assisted deposition methods, such as PECVD (Plasma-Enhanced Chemical Vapour Deposition), and more specifically, large surface diamond deposition methods. These methods generally require high concentrations of species in the plasma generated, and preferably on extended surfaces, to accelerate the deposition speed and/or cadence. The applicator such as introduced above allows to respond to this necessity.

According to an example, the inner conductor and the outer conductor can together form a cylindrical coaxial structure extending in a main propagation direction. The inner conductor can have, in a transverse direction perpendicular to the main propagation direction, an outer radius r₁ and the outer conductor can have, in the transverse direction, an inner radius r₂. The outer radius r₁ and the inner radius r₂ can be such that, with r₁ equal to d₁/2 and r₂ equal to d₂/2:

$$0.2 < \frac{{r}_{2} - {r}_{1}}{{r}_{2}} < 0.55$$

A second aspect relates to a high-frequency wave coupler for producing a plasma, comprising:
a coaxial structure formed from an inner conductor, and from an outer conductor, configured to be connected to a high-frequency wave generator,
a high-frequency wave applicator according to the first aspect, the coaxial structure of the applicator being disposed in the continuity of the coaxial structure of the coupler.

According to an example, the high-frequency wave applicator is configured to be removably fixed to the coaxial structure of the coupler. The applicator can thus be mounted on different coaxial coupler structures. These coaxial structures, of a lesser cost, can be designed to ensure a good coupling with the wave discharge coming from the generator, for different plasma impedances, for one same applicator. The use of a high-frequency wave coupler is therefore made more flexible. Furthermore, if only one from among the applicator and the coaxial structure is damaged, it is not necessary to change all of the coupler. According to an example, the applicator can be configured to be fixed manually by a user to the coaxial structure of the coupler.

A third aspect of the invention relates to a device for producing a plasma comprising a chamber and at least one high-frequency wave coupler according to the second aspect.

By the features of the coupler, and in particular of the applicator, the plasma production device has several advantages with respect to the current solutions. The reliability of the device is further increased by the improvement of the dissipation of the energy flows on the at least one coupler, while offering a good coupling, even an improved coupling.

The applicator could be mounted on different coaxial coupler structures, of a lesser cost, the associated investment costs are reduced, while allowing to use different operating conditions. The device is therefore adapted to different methods, and in particular to high-speed plasma-assisted and/or large deposition cadence methods.

According to an example, the device can comprise a plurality of couplers, the couplers being disposed on at least two, even three, walls of the chamber so as to form an at least two-dimensional, even three-dimensional network. The applicator allowing to extend the power deposition zone, and therefore that of producing plasma, a plurality of couplers can be used to obtain uniform plasmas on large dimensions. A species high-density uniform plasma can be obtained, which allows to considerably increase the speed of the methods implementing the device. Furthermore, the number of parts to be treated can be increased by increasing the number of couplers and, therefore, the volume of plasma generated. Thus, the production costs are decreased.

### BRIEF DESCRIPTION OF THE FIGURES

The aims, objectives, as well as the features and advantages of the invention will emerge best from the detailed description of an embodiment of the latter, which is illustrated by the following accompanying drawings, wherein:

FIG. 1 represents a view along a longitudinal cross-section of a coupler illustrating the state of the art.

FIG. 2 represents a view of the chamber of a plasma production device, according to an embodiment of the invention.

FIG. 3 represents a view along a longitudinal cross-section of a coupler, according to an embodiment of the invention.

FIG. 4 represents a view along a longitudinal cross-section of an applicator, according to a first embodiment of the invention.

FIG. 5 represents a view along a longitudinal cross-section of an applicator, according to a second embodiment of the invention.

FIG. 6 represents a view along a longitudinal cross-section of an applicator, according to a third embodiment of the invention.

FIG. 7 represents a view along a longitudinal cross-section of an applicator, according to a fourth embodiment of the invention.

FIG. 8 is a graph representing the surface distribution of power (in W·cm⁻²) on the front end of the applicator for several radius values of the inner conductor, according to an embodiment of the invention.

FIG. 9 is a graph of the insertion losses, in relative values, represented according to the relative dimensions of the applicator according to different embodiments of the invention.

FIG. 10 is a graph of the relative variation of the vacuum impedance, i.e. without plasma generation, on the front end of the applicator, standardised at its characteristic impedance, and represented according to the relative dimensions of the applicator according to different embodiments of the invention.

FIG. 10A is a graph of the variation of the ratio Z_{N}/Z_{N}^{min} represented according to the relative dimensions of the applicator according to different embodiments of the invention.

The drawings are given as examples and are not limiting of the invention. They constitute principle schematic representations intended to facilitate the understanding of the invention and are not necessarily to the scale of practical applications. In particular, the relative dimensions of the different elements of the applicator are not necessarily representative of reality.

### DETAILED DESCRIPTION

Before starting a detailed review of embodiments of the invention, below are stated optional features which can possibly be used in association or alternatively:
the high-frequency wave has a frequency greater than 100 MHz. According to an example, the wave is a microwave wave, and in particular the wave has a frequency of between 300 MHz and 10 GHz. According to an example, the frequency can be 352 MHz, 433 MHz, 915 MHz, 2.45 GHz, 5.8 GHz,
the microwave passage dielectric can be in a thin window configuration. More specifically, the passage dielectric can be disposed at a front end of the propagation medium, and extend, in the main propagation direction, over a length substantially equal to a multiple of a tenth of a quarter of the wavelength of the wave and strictly less than a quarter of the wavelength of the wave. The passage dielectric is thus in a so-called thin window configuration. According to an example, the wavelength of the wave is its wavelength in the passage dielectric,
the coaxial structure can have a rotational symmetry about its axis,
the inner conductor can have, on a portion extending from a front end of the inner conductor, a narrowing so as to have, in the transverse direction, from the portion and to its rear end, a second outer dimension d_{1′}, between two points of its outer surface relatively opposite the axis of the coaxial structure, the first outer dimension d₁ being greater than the second outer dimension d_{1′},
the applicator can comprise a so-called overlay dielectric having a solid body and covering at least one front end of the inner conductor,
the passage dielectric can be disposed at a front end of the propagation medium, and the overlay dielectric can further cover a front end of the outer conductor and the passage dielectric,
the passage dielectric and the overlay dielectric can form an assembly having a common body without discontinuity,
the assembly formed by the passage dielectric and the overlay dielectric can have, in the main propagation direction and at the propagation medium, a length substantially equal to a multiple of a tenth of a quarter of the wavelength of the wave and strictly less than a quarter of the wavelength of the wave. According to an example, the wavelength of the wave is its wavelength in the passage dielectric,
the applicator can further comprise a cooling module disposed in the inner conductor, the cooling module comprising a cooling chamber delimited by a front end of the inner conductor. The inner conductor can have a reduced thickness at the level of the cooling chamber,
the thickness e₁₁₂ of the inner conductor at the cooling chamber can be less than or equal to

$${e}_{11} \times \frac{{k}_{11}}{{k}_{14}}$$

where k₁₁ and k₁₄ represent respectively the thermal conductivities of the inner conductor and of the overlay dielectric and e₁₁ the thickness of the inner conductor,
the applicator can comprise an overlay dielectric having a solid body and covering at least one front end of the inner conductor, and a ceramic junction disposed in contact between at least the overlay dielectric and the inner conductor, and preferably in contact between the inner conductor and the overlay dielectric and in contact between the inner conductor and the passage dielectric,
the passage dielectric, the ceramic junction and the inner conductor can be formed of materials, the ratio of which between them of their thermal expansion coefficients is between 0.5 and 1.5,
the applicator can further comprise a solder bead disposed between the passage dielectric and the outer conductor,
the passage dielectric, the solder bead and the outer conductor can be formed of materials, the ratio of which between them of their thermal expansion coefficients is between 0.5 and 1.5.

Below in the description, use will be made of terms such as “longitudinal”, “transverse”, “front” and “rear”. These terms must be interpreted relatively, relative to the normal position of use of the high-frequency wave applicator or of the coupler in the plasma production device. For example, by “front” end, this means the end of the applicator or of the coupler rotated towards the chamber of the plasma production device. The “rear” end means the end of the applicator or of the coupler rotated opposite, i.e. towards the outside of the plasma production device. “Longitudinal” means, with respect to the main extension direction of the applicator or of the coupler, parallel to the main propagation direction of the waves.

“Inner” means the elements or the faces rotated towards the inside of the applicator or of the coupler, and “outer” means the elements or the faces rotated towards the outside of the applicator or of the coupler. According to an example, the coaxial structure of the applicator and of the coupler having a central axis A, “inner” means the elements or the faces rotated towards this axis, and “outer” means the elements or the faces rotated opposite this central axis.

By a parameter “substantially equal to/greater than/less than” a given value, this means that this parameter is equal to/greater than/less than the given value, within 10% or less, even within 5% or less, of this value.

By a material of an element of the applicator or of the coupler with the basis of a compound A, this means an element comprising this compound A and possibly other materials, even the material is mainly formed of this compound A.

The thickness of an element or of a wall is measured, for at least one considered portion, at each point of the surface of the element or of the wall for the at least one considered portion, in a direction perpendicular to the tangent at this point.

The plasma production device 3 is described in reference to FIG. 2. The device comprises a chamber 30 having several walls 300. At least one high-frequency wave coupler 2 is disposed on a wall 300 of the chamber 30. The coupler 2 aims to ensure the propagation of an electromagnetic wave from a microwave generator to the inside of the chamber 30 with a minimum power loss. The coupler 2 further allows to couple an electromagnetic wave 4, preferably high-frequency, transmitted by the coupler to the electrons. This coupling allows to ionise a gas or a gas mixture present in the chamber 30 to generate a plasma. The frequency of the wave can be greater than 100 MHz. More specifically, the frequency of the wave can be in the range of microwaves, and for example between 300 MHz and 10 GHz. Below, the non-limiting example is referred to, wherein the wave is a microwave wave.

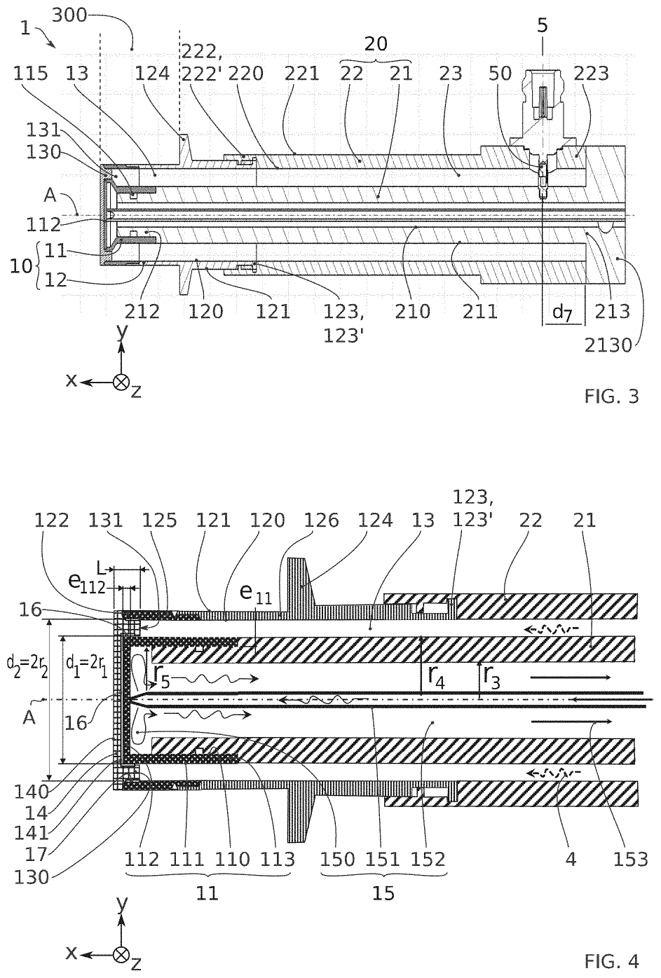

For this, the device 3 can comprise gas introduction modules configured to supply gas or the gas mixture into the chamber 30, as well as pumping modules, not represented in FIG. 3 and known to a person skilled in the art. The gas introduction modules and the pumping modules allow to maintain the pressure of the gas to be ionised at a desired value, chosen in particular according to the nature of the gas, and the desired density of species in the plasma generated.

Typically, the pressure of the gas or of the gas mixture can be between a few milliTorr to a few tens of Torr (corresponding to around a few tenths of Pa to a few thousands of Pa, in the international unit system). More specifically, the plasma production device 3 is configured to operate in the range of high pressures, i.e. at a pressure greater than 1 Torr, corresponding to 133 Pa. Furthermore, the device 3 can be configured to operate at a high microwave power leading to high power densities, for example, at a power density greater than 10 W/cm².

Indeed, the plasma production device 3 comprises a coupler 2, configured to support the application of high powers and high pressures. Thus, the device 3 is adapted to the production of plasmas of very high densities of species, for example in the methods for treating high-speed plasma and/or high production cadence. As a non-limiting example, in particular plasma-enhanced chemical vapour deposition (PECVD) methods, such as deposition of diamond, deposition of polycrystalline silicon, deposition of anticorrosive film, resin removal are considered.

The coupler 2 can be disposed at a wall 300 of the chamber 30 so as to be flush with this wall 300 according to the example illustrated in FIG. 2, or inserted at least partially into the chamber 30. Preferably, the coupler 2 is disposed so as to be flush with the wall of the chamber, to increase the uniformity of the plasma.

The device 3 can comprise a plurality of couplers 2, in order to form a network extending over at least one wall 300 of the chamber 30. By increasing the number of couplers, the volume of the plasma generated can be extended. Thus, the surface treated by the plasma and/or the number of parts to be treated can be increased, leading to a decrease in the production costs and allowing the implementation of methods for treating large surfaces. According to an example, a plurality of couplers 2 is disposed on at least two walls 300, in order to form a two-dimensional network. According to the example illustrated in FIG. 2, a plurality of couplers 2 is disposed on three walls 300, in order to form a three-dimensional network. Thus, the surface treated by the plasma and/or the number of parts to be treated can be further increased. Furthermore, it is possible to treat an object having a complex surface, for example the surface of the object extends into the three dimensions of the space.

The microwave coupler 2 is now described in reference to FIG. 3. The coupler 2 comprises a rear part and a front terminal part, referenced below by the term microwave applicator 1. The rear part of the coupler 2 and the applicator 1 comprise an inner conductor 11, 21, also referenced in the field by the term “central core”, and an outer conductor 12, 22, also referenced in the field by the term “shielding”. The inner conductor 11, 21, and the outer conductor 12, 22 are electrically conductive structures. The inner conductor 11, 21 extends in a main direction x between a front end 112, 212 intended to be directed towards the inside of the chamber 30 of the device 3, and a rear end 113, 213. The outer conductor 12, 22 extends in a main direction x between a front end 122, 222 intended to be directed towards the inside of the chamber 30 of the device 3, and a rear end 123, 223. For the rear part of the coupler 2 and the applicator 1, the outer conductor 12, 22 surrounds the inner conductor 11, 21, at least partially in a main direction x, and form a coaxial structure 10, 20 having a central axis A parallel to the main direction x. According to an example, each coaxial structure 10, 20 has a rotational symmetry about the central axis A called rotational axis. For example, the inner conductor 11, 21 and the outer conductor 12, 22 are cylindrical. Below, equivalently, the rear part of the coupler 2 is referenced by coaxial structure 20.

In order to transmit the microwaves of the rear end of the coupler 2 to the front end of the applicator 1 where the plasma is produced, a propagation medium 13, 23 is delimited by the outer surface 111, 211 of the inner conductor 11, 21 and the inner surface 120, 220 of the outer conductor 12, 22. The propagation medium 13, 23 is a dielectric medium, and therefore transparent to microwaves. This medium extends in a main propagation direction of the microwaves, parallel, even combined, to the direction x. The propagation medium 13, 23 can be formed of one from among several dielectric materials, such as air, quartz, and alumina. As illustrated in FIG. 3, the coaxial structure 13 of the applicator 1 and the coaxial structure 20 of the coupler 2 can be disposed in the continuity of one another.

The coupler 2 can be connected to a microwave generator 5 and be configured to inject microwaves into the propagation medium 13, 23. For this, the inner conductor 21 has, at its rear end 213, a bottom 2130 located at a distance d₇ from the connector for injecting microwaves 50 in the direction x, and delimiting the propagation medium 23 at the rear ends 213, 223 of the inner 21 and outer 22 conductors. This distance d₇ is generally chosen as a quarter of a wave λ/4, with λ the wavelength of the microwaves. It is noted that this distance d₇ can be different according to the design of the coupler 2, and in particular, of its coaxial structure 20.

The microwave applicator 1 can be arranged at a wall 300 of the chamber 30 according to the example illustrated in FIG. 2. For thus, the applicator 1 can comprise an abutment module 124, for example with a fixed abutment 124 disposed on the perimeter of the outer conductor 12. It is understood that according to the arrangement of the abutment module 124, the applicator 1 can be flush with the wall 300 of the chamber 30, or be inserted at least partially into the chamber 30.

According to an example, the applicator 1 and the rear part of the coupler 2 can form one single and same part. Alternatively, the microwave applicator 1 can be configured to be removably fixed to the coaxial structure 20 of the coupler 2. The microwave applicator 1 can thus be mounted on any coaxial structure 20 of the coupler 2 configured such that the coupler transmits the microwaves from one end to another of the coupler 2. It is known to a person skilled in the art that the coaxial structures 20, of a lesser cost, can be designed to ensure a good coupling with the discharge of microwaves coming from the generator 5. For example, different coaxial structures 20 can be used for different plasma impedances, i.e. different pressure and power windows of use, for one same applicator 1. The use of the microwave coupler 2 is therefore made more flexible. The investment cost associated with the device 3 is further reduced, since it is possible to use the applicator 1 for different operating conditions and, therefore different treatment methods. Furthermore, if only one from among the applicator 1 and the coaxial structure 20 of the coupler 2 is damaged, it is not necessary to change the assembly of the coupler 2.

The applicator 1 can be fixed to the coaxial structure 20 of the coupler 2 by means of tools, or preferably manually by a user. For this, the applicator 1 can comprise a complementary fixing module 123′ of a fixing module 222′ of the coaxial structure 20 of the coupler 2, and configured to secure the applicator 1 to the coaxial structure 20. For example, these fixing modules have complementary threads. According to another example, these fixing modules have complementary reliefs specific to being clipped. According to the example illustrated in FIG. 2, the fixing module 123′ can be disposed at the rear end 123 of the outer conductor 12 of the applicator 1, and the fixing module 222′ can be disposed at the front end 222 of the outer conductor 22. Furthermore, the inner conductor 11 of the applicator can have a profile complementary to the front end 212 of the inner conductor 21 of the coaxial structure 2, at its rear end 113. In order to perform a vacuum sealing between the inner conductor 11, 21, a seal, and for example, an O-ring 115, can be disposed at their interface. Furthermore, the contact surface between the inner conductors 11, 21 extends in the direction 11 to improve the thermal transfer along inner conductors 11, 21, as well as ensuring a good mechanical guiding when the applicator 1 is mounted on the coaxial structure 20.

Moreover, the outer conductor 22 of the coaxial structure 20, even the outer conductor 12 of the applicator has a nominal diameter compatible with the standards, such as the standards ND40 (40 mm), ND25 (25 mm), ND16 (16 mm).

The microwave applicator is now described in detail in reference to FIGS. 4 to 7. When a coupler 2 operates a high power and at high pressure, the applicator 1 in contact with the plasma is exposed to significant energy flows, which conveys an exposure to significant heat quantities. The applicator 1 is, in this case, configured for these significant energy flows, by an effective distribution of heat and its dissipation. Thus, the thermomechanical constraints leading to stresses and deformations, even a mechanical fracture of the elements of the applicator 1 are reduced, even avoided.

The applicator 1 has, more specifically, a configuration of the inner 11 and outer 12 conductors, as well as an assembly of different materials allowing its operation without damage, in particular when the energy flow to which the coupler 2 is exposed becomes significant.

For this, in a transverse direction y, perpendicular to the main propagation direction x, the inner conductor 11 has a first outer dimension d₁ between two points of its outer surface 111 relatively opposite the axis of the coaxial structure 10, and the outer conductor 12 has an inner dimension d₂ between two points of its inner surface 120 relatively opposite the axis of the coaxial structure 10, the first outer dimension d₁ and the inner dimension d₂ being relatively chosen so as to allow a good surface distribution of power, while maintaining a good coupling with the plasma and a low level of insertion losses.

The increase or the difference of the dimension d₁ of the inner conductor 11 with respect to the dimension d₂ of the outer conductor 12 allows to considerably improve the surface distribution of power. However, this increase or difference can induce, on the one hand, a quasi-exponential increase in insertion losses (α_{c}), which decreases the power transmitted to the plasma and, on the other hand, an increase in the impedance in the outlet plane of the vacuum-radiating applicator Z_{V} standardised to the characteristic impedance Z₀, referenced Z_{N} below, with Z_{N}=Zᵥ/Z₀, which degrades the coupling.

In this case, the dimension d₁ of the inner conductor 11 with respect to the dimension d₂ of the outer conductor 12 can be limited according to the insertion losses (α_{c}) in the conductors 11, 12 of the applicator and according to the standardised impedance Z_{N}. For example, at constant dimension d₂, according to a standardised diameter of the outer conductor, and at a fixed frequency, the dimension d₁ is chosen such that:
Δα_{c}/α_{cmin} is less than 180%, where Δα_{c} corresponds to the difference between α_{c} and α_{cmin}, α_{cmin} corresponding to the insertion loss coefficient in the inner 11 and outer 12 conductors;
Z_{N}/Z_{Nmin} is less than 1.65, where Z_{Nmin} is equal to (Z_{V}/Z₀)ₘᵢₙ, Z_{Nmin} corresponding to an impedance in the outlet plane of the vacuum-radiating applicator close to the characteristic impedance Z₀, Z_{Nmin} pushing towards 1.

Starting with the conditions above, the decrease in the dimension d₁ of the inner conductor 11 with respect to the dimension d₂ of the outer conductor 12 allows to minimise, both the insertion losses, and the standardised impedance. However, this decrease reduces the distribution surface of the power. In this case, the maximum decrease of the dimension d₁ of the inner conductor 11 can be limited by the minimum values of the insertion losses (α_{c}) and of the standardised impedance Z_{N}. Beyond these minimum values, not only the power is disadvantageously distributed over a very small surface, but also the insertion losses and the standardised impedance Z_{N} increase drastically again.

During the development of the invention, a ratio of the dimensions d₁ and d₂ of the respectively inner 11 and outer 12 conductors has been highlighted in order to obtain the extension of the power distribution zone, while maintaining a low level of insertion losses and of the ratio of standardised impedances Z_{N}/Z_{Nmin}, i.e. impedances in the outlet plane of the vacuum-radiating applicator quite close to the characteristic impedance of the applicator (Z_{V}/Z₀<10).

The first outer dimension d₁ and the inner dimension d₂ are such that

$$0.2 < \frac{{d}_{2} - {d}_{1}}{{d}_{2}} < 0.55$$

According to the example wherein the inner 11 and outer 12 conductors are cylindrical, with d=2r, the following ratio is obtained.

$$0.2 < \frac{{r}_{2} - {r}_{1}}{{r}_{2}} < 0.55$$

Preferably, the decrease of the dimension d₁ of the inner conductor 11 is limited by Δα_{c}/α_{cmin}>15% and Z_{N}/Z_{Nmin}>1.01 to have a sufficiently extended power distribution surface. Thus, the ratio of the dimensions presented in the two abovementioned ratios can be between 0.2 and 0.55. The ratio of the dimensions presented in the two abovementioned ratios can be more limited and between 0.2 and 0.4.

Thus, the surface power is distributed on the surface of the inner conductor 11, while minimising the insertion losses and the standardised impedance, and more specifically by keeping the insertion losses low of between 15 and 180*α_{cmin} and of the impedances of 1.01 to 1.65*Z_{Nmin}, i.e. relative differences of 0.01 to 0.65*Z_{Nmin}.

Below, it is considered, in a non-limiting manner, that the inner 11 and outer 12 conductors are cylindrical, and therefore form a cylindrical coaxial structure 10.

As an example, FIG. 8 illustrates the surface distribution of the microwave power (in W·cm⁻²) on the front end of the applicator 1 for several radius values of the inner conductor 11, for an argon discharge at a pressure of substantially 1 Torr by a couple of nominal diameter 25 mm when it is powered by 30 W of microwave power at 915 MHz. It is observed that the more the radius r₁ of the inner conductor increases from 3.1 to 9.5 mm, the more the microwave power is distributed along the inner conductor 11 in a direction transverse to the rotational axis A.

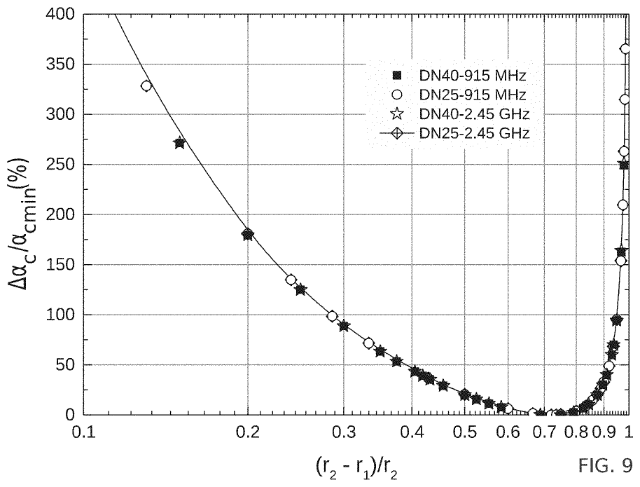

FIG. 9 illustrates a graph of the insertion losses, in relative values, calculated according to the ratio (r₂−r₁)/r₂ for a coaxial waveguide made of aluminium of different nominal diameters (abbreviated to ND) given in mm, with an air propagation medium 13 at a microwave frequency of 915 MHz or of 2.45 GHz. According to the example illustrated in FIG. 9, a loss minimum of α_{cmin}=3.10⁻³ m⁻¹ can be obtained for a radius r₁ of 3 to 4 mm (that is a relative loss of Δα_{c}/α_{cmin}=(α_{c}−α_{cmin})/α_{cmin}≈0), but the power deposited in the plasma, as illustrated by FIG. 8, remains localised on a radius zone of around the radius r₁ of the inner conductor, which is broadly less than the radius r₂ of the outer conductor 12, of 12.5 mm according to this example. For a radius r₁ of between 7 mm and 9.5 mm, the relative insertion losses Δα_{c}/α_{cmin} are less than 180% while allowing a better surface expansion of power, according to FIG. 8.

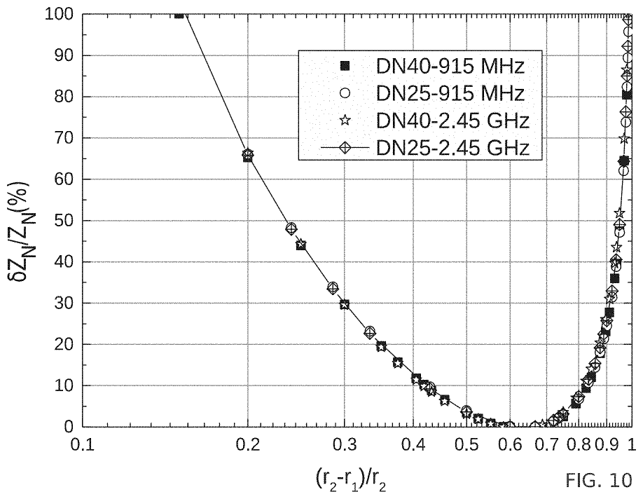

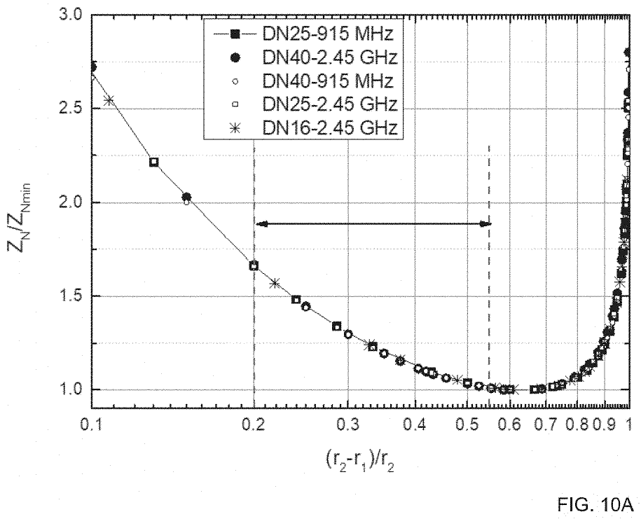

FIG. 10A is proposed as a reduced version of FIG. 10 so as to make reading it easier by a person skilled in the art. In this regard, FIG. 10A proposes a direct representation of the ratio Z_{N}/Z_{N}^{min} instead of the representation of the relative values (Z_{N}/Z_{N}^{min}−1)×100 in % that FIG. 10 gives. In addition, FIG. 10A illustrates the range of values of the relative dimensions of the applicator such as introduced above.

For the three values considered as an example in FIG. 8 for an applicator ND25 or radius r₂ of 12.5 mm, FIG. 10 shows that the best coupling by having Z_{N}/Z_{Nmin}≈1.03>1.01, corresponds to the radius r₁ of 3.1 mm, but the ratio (d₂−d₁)/d₂=0.75 does not satisfy the criterion (d₂−d₁)/d₂<0.55. In addition, according to FIG. 8, the power is concentrated on a narrow distribution zone, of radius comparable to the radius r₁ which leads to very high power densities (2 kW/cm² for a power of 600 W supplied to the applicator). The maximum value (d₂−d₁)/d₂=0.55 is reached for a radius r₁ of 5.6 mm. For one same radius r₂, the coupling corresponding to the best surface distribution of power (0.2 kW/cm² for a power of 600 W) is obtained for the radius of 9.5 mm with the ratios (d₂−d₁)/d₂=0.24 and Z_{N}/Z_{Nmin}≈1.48 included in the range of validity. The maximum value (d₂−d₁)/d₂=0.2 is reached for a radius r₁ of 10 mm. According to this example of an embodiment of an applicator ND25 of radius r₂ of 12.5 mm, this can therefore have a radius r₁ of maximum 10 mm and of minimum 5.6 mm to respond to the desired criteria from the standpoint of insertion losses and plasma coupling.

The insertion losses being kept at a low level and the coupling between the microwaves 4 and the electrons being ensured, the applicator 1 allows the production of a high-power plasma with an advantageous distribution of power and therefore the dissipation of energy flows on the surface of the applicator. The thermomechanical strength of the applicator 1 is thus improved. Its reliability is therefore increased, which allows to improve the stability and the reproducibility of the methods wherein the applicator 1 is used. The applicator 1 can thus be used for the high-power production of plasma and in the range of high pressures, for the production of plasma with a high density of species.

This configuration of the applicator 1 allows to extend the power deposition zone of the microwaves and, therefore that of generating plasma. This has, as a consequence, the reduction of discontinuity between the generation zones when a plurality of couplers 2 is disposed in a plasma production device 3. Uniform plasmas over large dimensions can thus be obtained.

Synergistically, a uniform plasma with a high density of species can be generated, in particular when couplers are disposed in an at least two-dimensional network. This allows to considerably increase the speed of a treatment method implementing the applicator 1. Uniform and high-pressure treatment methods can be implemented over large surfaces, which resolves one of the main challenges of high-pressure plasmas of current solutions. Moreover, the maintenance costs are reduced, thanks to the increase of the reliability of the applicator 1.

The propagation medium 13 of the applicator 1 is now described in detail. The propagation medium 13 is constituted of at least one dielectric transparent to microwaves, and for example, air. The propagation medium 13 further comprises a passage dielectric 130 of the microwave 4 have a so-called sealing solid body, based on a dielectric material, and disposed between the inner conductor 11 and the outer conductor 12. The term “solid” specifies a solid state with respect to a gaseous or liquid state. The passage dielectric 130 is configured so as to allow the passage of the microwave 4 from the propagation medium 13 to the chamber 30. The passage dielectric is further configured so as to maintain a vacuum sealing between the chamber 30 and the rest of the propagation medium 13, which is for example, at atmospheric pressure.

According to the example illustrated in FIG. 4, the passage dielectric can be positioned at the front ends 112, 122 of the inner 11 and outer 12 conductor, so as to form a dielectric stopper at the front end 131 of the propagation medium 13.

The passage dielectric 130 of the microwaves can be in a thin window configuration. For this, the passage dielectric 130 has a length L, in the main propagation direction x, substantially equal to a multiple of a tenth of a quarter of the wavelength of the microwave 4 in the passage dielectric 130. This configuration has several advantages, with respect to the current solutions, wherein the length of the passage dielectric is a multiple of a half and/or a quarter of the wavelength of the microwaves. The length of the passage dielectric 130 can be less than that of current solutions, which facilitates the dissipation of the energy flows in the dielectric, and therefore its cooling. Furthermore, a thin window limits the impedance mismatch between the applicator 1 constructed and that provided by digital simulations. This mismatch is in particular induced by possible differences between the dielectric permittivity of the passage dielectric 130, indicated by the suppliers, used as input data during the digital design of the couplers 2, and the actual dielectric permittivity. Thus, the applicator 1 allows to limit, even avoid, a power loss of the microwaves.

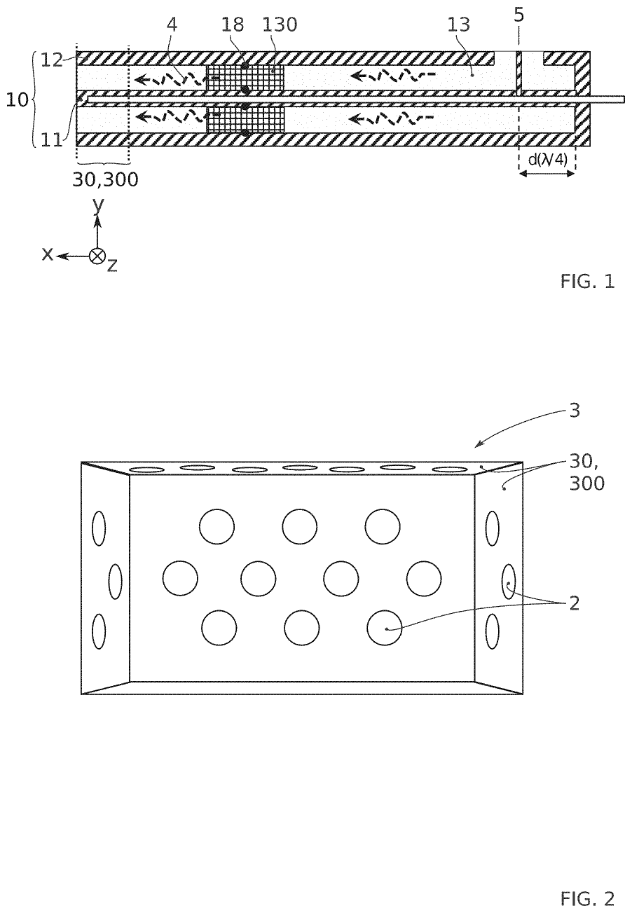

To guarantee the sealing by the passage dielectric 130 between the dielectric 130 and the outer conductor 12, a bead 17 is disposed at their interface. A bead 17 corresponds to a metal connection between the dielectric 130 and the outer conductor 12. The bead is preferably a solder bead 17, allowing a fusionless connection of the dielectric 130 and of the outer conductor 12, different from a solder bead. The solder bead 17 allows to replace an O-ring 18 generally used for this function, as illustrated in FIG. 1. Yet, during the use of a coupler 2, an O-ring disposed at the end of the applicator 1 in contact with the plasma, can overheat and be damaged, even destroyed. This can lead to electromagnetic leakages, even coupling instabilities. Furthermore, the solder bead 17 confers a mechanical solidity to the applicator. Preferably, and as described in more detail below, the solder bead is made of metal.

Synergically, the thin window configuration facilitates the soldering operation. During this operation, it is easier to control the diffusion of the solder bead over a shorter distance and thus ensure the sealing.

The applicator further comprises an overlay dielectric 14, a part with the basis of a dielectric material configured to cover at least the front end 112 of the inner conductor 11. According to an example, the overlay dielectric 14 further covers the front end 122 of the outer conductor 12 and the passage dielectric 130 on its front face. The overlay dielectric 14 can thus cover all of the surface of the applicator 1 in contact with the plasma. The overlay of the surface of the applicator 1 allows to form a barrier to the chemical reactions which could be activated by the high temperature of this surface and, therefore, to protect the applicator against a contamination of the method. The reliability of the applicator is thus further increased.

The overlay dielectric 14 and the passage dielectric 130 can further be juxtaposed in the direction x without discontinuity. For example, it can be provided that the overlay 14 and passage dielectrics of the microwaves 130 are juxtaposed without forming a common body, these dielectrics being, for example, assembled using a ceramic junction.

Preferably, the overlay dielectric 14 can form a common body with the passage dielectric 130. The overlay dielectric 14 and the passage dielectric 130 can be directly juxtaposed in the direction x without discontinuity and be formed of the same material. Thus, the mechanical adjustment stresses between the passage dielectric 130 and the overlay dielectric 14 are thus avoided. The problems with misalignment of the dielectrics during mounting are further offset. Moreover, the formation of microcavities between the passage dielectric 130 and the overlay dielectric 14 is thus avoided. The formation of micro-plasmas in these microcavities can cause a local overheating and a deterioration of the applicator 1. The dissipation of energy flows on the surface of the applicator is therefore further improved.

The assembly formed by the passage dielectric 130 and the overlay dielectric 14 can be in a thin window configuration. For this, the assembly formed by the passage dielectric 130 and the overlay dielectric 14 can have a length L, in the main propagation direction x and at the propagation medium 13, substantially equal to a multiple of a tenth of a quarter of the wavelength of the microwave 4 in the passage dielectric 130 and strictly less than a quarter of the wavelength of the wave.

The overlay dielectric 14 can be thin, and in particular as thin as possible. The minimum thickness of the overlay dielectric 14 is more specifically imposed by its mechanical strength. For example, the thickness of the overlay dielectric 14 is substantially greater than 100 μm (10⁻⁴ m).

To improve the dissipation of heat on the surface of the applicator 1 in contact with the plasma, the applicator comprises a cooling module 15 allowing an effective transfer of the quantity of heat, deposited by the plasma on the applicator 1. This cooling module 15 is configured to make a cooling liquid 153 circulate, for example, water, to dissipate the heat received by the applicator 1 from the plasma by transferring it to the cooling liquid 153.

As illustrated by FIG. 4, the cooling module 15 can be disposed inside the inner conductor 11. The cooling module 15 can comprise a cooling chamber 150, configured to engage with an injection element 151 of the cooling liquid 153 disposed on the coaxial structure 20 of the coupler 2, and a discharge conduit 152 of this liquid.

The cooling chamber 150 can be delimited by the front end 112 of the inner conductor 11, by its inner surface 110. The injection element 151, such as a bevelled needle, can lead into the cooling chamber 150, facing the front of the applicator 1.

The discharge conduit 152 can extend from the cooling chamber 150 in the direction x in the inner conductor 21 of the coaxial structure until crossing the bottom 2130, so as to discharge the cooling fluid 153 once the heat transfer is performed. The discharge conduit 152 can more specifically be delimited by the inner surface 210 of the inner conductor 21.

According to the example illustrated by FIG. 4, the inner radius r₅ of the inner conductor 11 can be greater than the inner radius r₃ of the inner conductor 21. Thus, the cooling chamber 150 allows to make the cooling liquid in contact circulate with a maximum of the front face 112 and with the inner surface 110 of the outer conductor.

The applicator 1 can be configured so as to have no air pocket between the cooling chamber 150 and the overlay dielectric 14. For this, the applicator 1 can comprise a ceramic junction 16, a part with the basis of a ceramic material disposed in contact between at least the overlay dielectric 14 and the inner conductor 11, and preferably also in contact between the inner conductor 11 and the passage dielectric 130, and configured to establish a junction between these elements. The ceramic junction 16 can be configured so as to establish a direct contact, without film or air pockets, between the inner conductor 11 and the overlay dielectric 14 and passage dielectric 130. Indeed, the presence of layers or air pockets is damaging from the standpoint of heat dissipation due to the very low thermal conductivity of air, of around 0.5 to 0.6 W·K⁻¹·m⁻¹ over a range of 800 to 1000 K, with respect to those of the surrounding materials, described in detail below, and for example alumina (30 W·K⁻¹·m⁻¹), Kovar (17 W·K⁻¹·m⁻¹), or also aluminium (238 W·K⁻¹·m⁻¹). Synergically, with the cooling module 15, the heat transfer and therefore the dissipation of the energy flows are further improved.

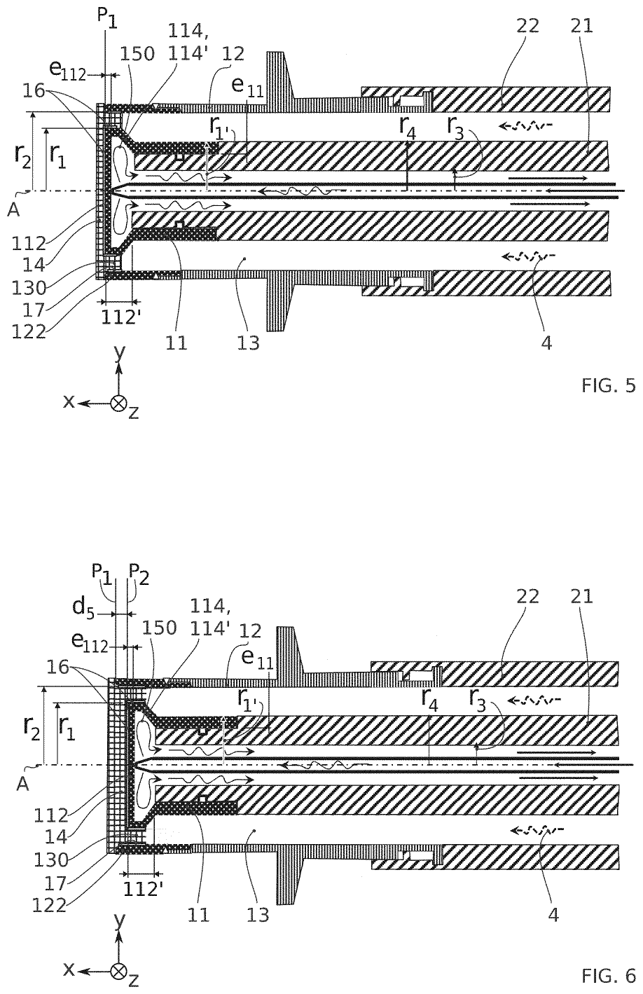

According to an example, the inner conductor 11 can have, on a portion 114, a narrowing 114′. More specifically, and as illustrated by FIGS. 5 to 7, the inner conductor 11 can have, from its first radius r₁ end, a narrowing 114′ to have from the portion 114 and to its rear end 113, a second radius r_{1′}, the first radius r₁ being greater than the second radius r_{1′}. Thus, in a direction going from the rear to the front of the applicator 1, the inner conductor 11 has a portion aligned with the inner conductor 21 of the coaxial structure 20, then has an extended portion 112′ on its front end 112. According to a projection perpendicular to the direction x, the perimeter of the portion aligned with the inner conductor 21 of the coaxial structure 20 can be completely comprised in the perimeter of the extended portion 112′. According to the example illustrated by FIGS. 5 to 7, and in a direction going from the front to the rear of the applicator 1, the narrowing 114′ extends from a rear end of the passage dielectric 130. The wall of the inner conductor 11 at the narrowing 114′ can further extend obliquely with respect to the direction x.

The outer radius r_{1′} of the inner conductor 11 and the outer radius r₄ of the inner conductor 21 can thus be reduced, while preserving the configuration of the end 112 of the inner conductor 11 allowing a compromise between distribution of heat flows and minimisation of insertion losses. The ratio of the radiuses r_{1′}/r₂, and r₄/r₂ can thus be decreased, to improve the transfer of microwaves, by minimising the phenomena of reflection and/or appearance of stationary waves. Subsequently, the applicator allows to further limit, even avoid, a loss of power of the microwaves.

The narrowing 114′ moreover allows to increase the inner surface 110 of the inner conductor 11 in contact with the cooling fluid 153 at the cooling chamber 150. The thermal transfer and therefore the dissipation of the energy flows are further improved.

With or without the narrowing 114′, the thickness e₁₁₂ of at least one part of the front end 112 of the inner conductor 11, at the cooling chamber 150, can be minimised. With the thickness of the inner conductor 11 being reduced, the cooling of the front end of the applicator 1 is facilitated. At the connection between the inner conductors 11, 21, the thickness e₁₁ of the inner conductor 11 can be between e₁₁₂ and 2*e₁₁₂.

The thickness e₁₁₂ of the inner conductor 11 and/or the thickness of the overlay dielectric 14 can more specifically be linked to the thermal resistance of each of the two materials forming these elements. This thermal resistance is preferably low to not induce significant temperature gradients in the materials, which would lead to damaging stresses and deformations, such as fissures in the passage dielectric 130 and/or in the overlay dielectric 14.

The thickness e₁₁₂ of the inner conductor 11 at the cooling chamber 150 can be less than or equal to:

$${e}_{11} \times \frac{{k}_{11}}{{k}_{14}}$$

where k₁₁ and k₁₄ respectively represent the thermal conductivities of the inner conductor 11 and of the overlay dielectric 14 and e₁₁ the thickness of the inner conductor.

According to an example, the thickness of the conductor 21, defined by the difference between its outer radius r₄ and its inner radius r₃, is greater than the thickness of the inner conductor 11 to improve the mechanical strength of the coupler 2.

The relative position of the inner 11 and outer 12 conductors is now described in reference to FIGS. 4 to 7. More specifically, the conductors can be in one same plane or offset against one another. As illustrated by FIGS. 4 and 5, the inner 11 and outer 12 conductors can be aligned such that their front end 112, 122 are disposed in one same plane P₁. Furthermore, the passage dielectric of the microwaves 130 can be aligned on its front face in the same plane.

Alternatively, the front end 112 of the inner conductor 11 can be disposed removed from the front end 122 of the outer conductor 12. According to the example illustrated in FIG. 6, the front end 112 of the inner conductor 11 can more specifically be disposed at a distance d₅ of the front end 122 from the outer conductor 12, d₅ which could preferably be limited such that the thickness of the assembly formed by the overlay dielectric 14 and the passage dielectric of the microwaves 130, at the front end of the passage medium 13 of the microwaves, that is in the thin window configuration.

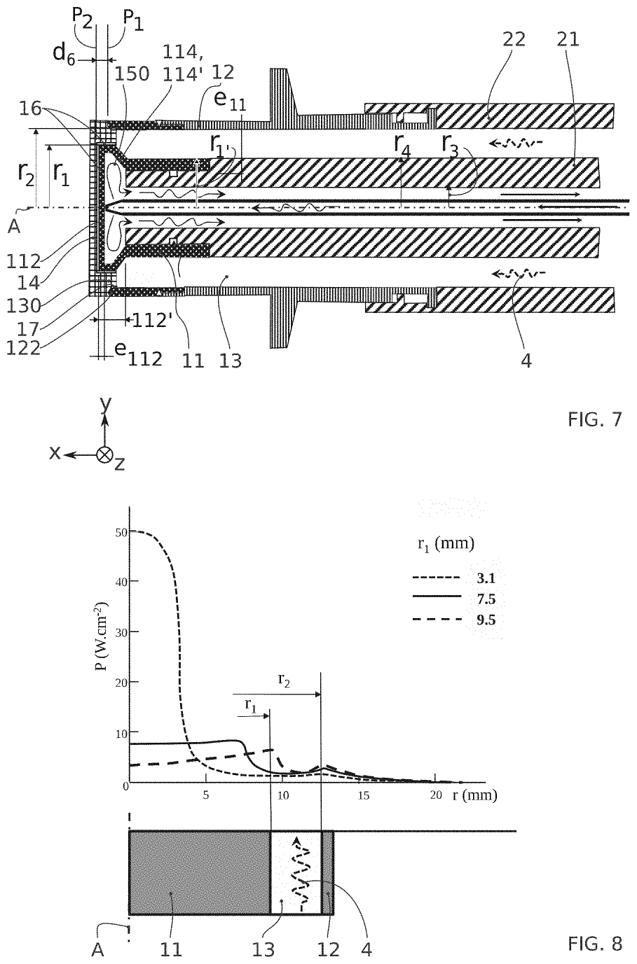

Alternatively, the front end 112 of the inner conductor 11 can be disposed in front of the front end 122 of the outer conductor 12. According to the example illustrated in FIG. 7, the front end 112 of the inner conductor 11 can more specifically be disposed at a distance d₆ of the front end 122 from the outer conductor 12, d₆ which could preferably be limited such that the thickness of the assembly formed by the overlay dielectric 14 and the passage dielectric of the microwaves 130, at the front end of the passage medium 13 of the microwaves, that is in the thin window configuration.

It is noted that although the examples illustrated in FIGS. 6 and 7 have a narrowing 114′, the relative different positions of the conductors 11, 12 can apply with or without the narrowing 114′. Furthermore, according to the relative position of the conductors 11, 12, the dimensions of the assembly formed by the passage dielectric 130 and the overlay dielectric 14 can be adapted, in particular, to respecting the thin window configuration.

As stated above, the different constitutive elements of the applicator 1 are formed of materials allowing its operation without damage, in particular when the energy flow to which the coupler 2 is exposed becomes significant. The materials chosen are preferably compatible from the thermal and chemical standpoint, in order to be able to:
solder between the outer conductor 12 and the passage dielectric 130, even the overlay dielectric 14,
produce the junction between the dielectrics 130, 14 and the inner conductor 11,
prevent the creation of thermal bridges and the appearance of thermomechanical constraints leading to stresses and deformations, even to the mechanical fracture, of the elements constituting the applicator 1, even the coupler 2,
guarantee the mechanical solidity of the assembly.

The materials which meet these criteria are now described. At the interfaces between different elements of the applicator 1, the materials of the elements are a given interface can have thermal expansion coefficients of these close materials, for example the ratio of which between them, or equivalently, the ratio two-by-two, is between 0.5 and 1.5, and preferably between 0.8 and 1.2. Thus, the deformation risk of these elements against one another is limited during the use of the applicator 1. This feature relates more specifically to the assembly formed by the overlay dielectric 14, the passage dielectric 130, the ceramic junction 15 and the inner conductor 11, and/or the assembly formed by the passage dielectric 130, the solder bead 17 and the outer conductor 12.

The overlay dielectric 14 preferably has a good chemical stability at high temperature, and preferably at a temperature greater than 300° C. For example, the overlay dielectric 14 is made of alumina Al₂O₃. The overlay dielectric 14 is thus stable with respect to the metal materials generally used to cover the front end of the couplers, such as aluminium or stainless steel. In addition, the metals have a lower melting point T_{f} (T_{f-Al}=660° C. against T_{f-Al2O3}=2054° C., at atmospheric pressure), and can induce a contamination of the plasma, and therefore of the method, with metal vapours.

The outer conductor 12 can comprise at least two portions formed of separate materials, in order to improve the chemical and physical compatibility with other elements close to the applicator, in particular concerning possible thermal deformations during the operation of the applicator 1.

In order to solder between the outer conductor 12 and the passage dielectric 130, even the overlay dielectric 14, the materials of these elements are preferably thermally compatible together and chemically with the material of the solder bead 17, comprising for example, a copper and silver alloy. The front end 122 of the inner conductor is therefore preferably iron, nickel and cobalt alloy-based with a low thermal dilatation coefficient, such as Kovar©, and the passage dielectric 130, even the overlay dielectric 14, made of alumina. An iron, nickel and cobalt alloy with a low thermal dilatation coefficient, such as Kovar©, can in particular be used to seal together the pairs of glass/metal or ceramic/metal materials in a wide temperature range and for multiple applications. It can therefore be used to solder with a dielectric, for example made of alumina Al₂O₃. Furthermore, Kovar© and alumina have close thermal expansion coefficients (TEC): TEC_{Kovar}≈5-6×10⁻⁶ K⁻¹ and TEC_{Al2O3}≈8−9×10⁻⁶ K⁻¹.

The outer conductor 22 and the inner conductor 21 of the coaxial structure 20 of the coupler 2 can be with the basis of a metal having a high thermal conductivity, such as silver, copper, aluminium, duralumin, a conductive brass, respectively having a thermal conductivity of 400, 380, 238, 160 and 120 W·K⁻¹·m⁻¹. Indeed, the conductors of the coaxial structure 20 are cooled very effectively by the bottom 2130 of the coupler 2, illustrated in FIG. 3, which increases the dissipation speed of the energy flows. It is noted that the choice of the metal can further be made so as to minimise the insertion losses of the microwaves. Preferably, the outer conductor 22 and the inner conductor 21 are aluminium-based.

The assembly formed by the outer conductors 12, 22 is preferably vacuum-sealed. For this, the outer conductor 12 can comprise a front portion 125 made of Kovar© and a rear portion 126 made of metal, the front portion 125 and the rear portion 126 being able to be, for example, welded together. In order to allow this welding, the metal of the rear portion 126 preferably has a melting point T_{f} close to the front portion 125. For example, the rear portion 126 is made of stainless steel (abbreviated to inox): T_{f-Kovar}=1450° C. and T_{f-inox}≈1500° C. As stated above, the portion 126 can be assembled to the outer conductor of the coaxial structure 20 by the fixing module 123′, for example by a thread.

The inner conductor 11 of the applicator is preferably made of iron, nickel and cobalt alloy with a low thermal dilatation coefficient, such as Kovar©. Indeed, aluminium is not very thermally compatible with the alumina of the overlay dielectric 14 and of the passage dielectric 130, for example in terms of thermal expansion coefficients (TEC_{Al2O3}≈8-9×10⁻⁶K⁻¹<<TEC_{Al}=23-25×10⁻⁶ K⁻¹).

The ceramic junction preferably has a good temperature stability and a high thermal conductivity. A ceramic adhesive, or equivalently, an alumina-based ceramic gluing cement can be used, such as 903HP having a melting point T_{f-903HP} equal to 1790° C., and a thermal conductivity of around 5.6 W·K⁻¹·m⁻¹. 903HP, further has a good chemical compatibility with alumina Al₂O₃ and Kovar©, as well as a close thermal expansion compatibility (TEC_{Kovar}≈5-6×10⁻⁶ K⁻¹, TEC_{903HP}=7.2×10⁻⁶ K⁻¹, TEC_{Al2O3}≈8-9×10⁻⁶ K⁻¹).

In view of the description above, it clearly appears that the invention proposes a high-frequency wave applicator allowing a good transfer, even a good coupling between an electromagnetic wave and electrons to produce a plasma, by improving the dissipation of the energy flows.

The invention is not limited to the embodiments described above and extends to all the embodiments covered by the claims.

In the description above, it is considered that the inner and outer conductors are cylindrical. The conductors can sometimes have the whole geometry allowing to form a coaxial structure and allowing the transfer and the coupling of a high-frequency wave.

### LIST OF REFERENCES

1. Microwave applicator
10. Coaxial structure
11. Inner conductor
110. Inner surface
111. Outer surface
112. Front end
112′. Extended portion
113. Rear end
114. Portion
114′. Narrowing
115. O-ring
12. Outer conductor
120. Inner surface
121. Outer surface
122. Front end
123. Rear end
123′. Fixing module
124. Abutment element
125. Front portion
126. Rear portion
13. Propagation medium
130. Passage dielectric
131. Front end
14. Overlay dielectric
140. Front face
141. Rear face
15. Cooling module
150. Cooling chamber
151. Injection needle
152. Discharge conduit
153. Cooling fluid
16. Ceramic junction
17. Solder bead
18. O-ring
2. Microwave coupler
20. Coaxial structure
21. Inner conductor
210. Inner surface
211. Outer surface
212. Front end
213. Rear end
2130. Bottom
22. Outer conductor
220. Inner surface
221. Outer surface
222. Front end
222′. Fixing module
223. Rear end
23. Propagation medium
3. Production device
30. Chamber
300. Walls
4. Wave
5. Microwave generator
50. Microwave injection connector

1. A high-frequency wave applicator for a coupler for producing a plasma, comprising:
an inner conductor and an outer conductor together forming a coaxial structure extending in a main propagation direction (x) of the high-frequency wave inside the coaxial structure,
a propagation medium of the high-frequency wave delimited by an outer surface of the inner conductor and an inner surface of the outer conductor, and comprising a so-called passage dielectric of the high-frequency wave, the passage dielectric comprising a sealing solid body disposed between the inner conductor and the outer conductor,
the inner conductor has, in a transverse direction (y) perpendicular to the main propagation direction (x), a first outer dimension d1 taken between two points of its outer surface relatively opposite an axis of the coaxial structure, and the outer conductor has, in the transverse direction (y), an inner dimension d2 taken between two points of its inner surface relatively opposite the axis of the coaxial structure,
the applicator being characterised in that, the first outer dimension d₁ and the inner dimension d₂ are such that:
$$0.2 < \frac{{d}_{2} - {d}_{1}}{{d}_{2}} < 0.55$$

2. The applicator according to claim 1, wherein the passage dielectric is disposed at a front end of the propagation medium, and extends, in the main propagation direction (x), over a length (L) substantially equal to a multiple of a tenth of a quarter of the wavelength of the wave and strictly less than a quarter of the wavelength of the wave.

3. The applicator according to claim 1, wherein the inner conductor has, on a portion extending from a front end of the inner conductor, a narrowing so as to have, in the transverse direction (y) and from the portion and to its rear end, a second outer dimension d_{1′} between two points of its outer surface relatively opposite the axis of the coaxial structure, the first outer dimension d₁ being greater than the second outer dimension d_{1′}.

4. The applicator according to claim 1, comprising a so-called overlay dielectric having a solid body and covering at least one front end of the inner conductor.

5. The applicator according to claim 4, wherein, the passage dielectric being disposed at a front end of the propagation medium, the overlay dielectric further covers a front end of the outer conductor and the passage dielectric.

6. The applicator according to claim 5, wherein the passage dielectric and the overlay dielectric form an assembly having a common body without discontinuity.

7. The applicator according to claim 6, wherein the assembly formed by the passage dielectric and the overlay dielectric has, in the main propagation direction (x) and at the propagation medium, a length (L) substantially equal to a multiple of a tenth of a quarter of the wavelength of the wave in the passage dielectric and strictly less than a quarter of the wavelength of the wave in the passage dielectric.

8. The applicator according to claim 1, further comprising a cooling module disposed in the inner conductor, the cooling module comprising a cooling chamber delimited by a front end of the inner conductor, the inner conductor having, at the cooling chamber (150), a reduced thickness.

9. The applicator according to claim 8, wherein the thickness e₁₁₂ of the inner conductor at the cooling chamber is less than or equal to
$${e}_{11} \times \frac{{k}_{11}}{{k}_{14}}$$
where k₁₁ and k₁₄ respectively represent the thermal conductivities of the inner conductor and of the overlay dielectric and e₁₁ the thickness of the inner conductor.

10. The applicator according to claim 1, comprising an overlay dielectric having a solid body and covering at least one front end of the inner conductor, and a ceramic junction disposed in contact between at least the overlay dielectric and the inner conductor.

11. The applicator according to claim 10, wherein the overlay dielectric, the passage dielectric, the ceramic junction and the inner conductor are formed of materials, of which the ratio between them of their thermal expansion coefficients is between 0.5 and 1.5.

12. The applicator according to claim 1, further comprising a solder bead disposed between the passage dielectric and the outer conductor.

13. The applicator according to claim 12, wherein the passage dielectric, the solder bead and the outer conductor are formed of materials of which the ratio between them of their thermal expansion coefficients is between 0.5 and 1.5.

14. A high-frequency wave coupler for producing a plasma comprising:
a coaxial structure formed of an inner conductor, and of an outer conductor, configured to be connected to a high-frequency wave generator,
a high-frequency wave applicator according to claim 1, the coaxial structure of the applicator being disposed in the continuity of the coaxial structure of the coupler.

15. The high-frequency wave coupler according to claim 14, wherein the high-frequency wave applicator is configured to be removably fixed to the coaxial structure of the coupler.

16. A device for producing a plasma comprising a chamber and at least one coupler according to claim 14.

17. The device for producing a plasma according to claim 16, comprising a plurality of couplers, the couplers being disposed on at least two walls of the chamber so as to form an at least two-dimensional network.
